(19) United States
(12) Patent Application Publication
(10) Pub. No.: US 2025/0261496 A1
(43) Pub. Date: Aug. 14, 2025

(54) Display Apparatus

(71) Applicant: LG Display Co., Ltd., Seoul (KR)

(72) Inventor: Seung Hee Kang, Paju-si (KR)

(21) Appl. No.: 19/035,360

(22) Filed: Jan. 23, 2025

(30) Foreign Application Priority Data
Feb. 13, 2024 (KR) 10-2024-0020508

(51) Int. Cl. H10H 29/854; H10H 29/49; H10H 29/855

(52) U.S. Cl. CPC H10H 29/854; H10H 29/49; H10H 29/8552

(57) ABSTRACT

A display apparatus including an oxide semiconductor is provided. The display apparatus includes a driving circuit and a light-emitting device on a display area of a device substrate. The driving circuit can be electrically connected to the light-emitting device. The driving circuit can include at least one thin film transistor. A semiconductor pattern of the thin film transistor can include an oxide semiconductor. The display area can be surrounded by a barrier line. The barrier line can include a hydrogen blocking material. A barrier trench can penetrate inorganic insulating layers stacked on the barrier line. A cover pattern can be on a side-wall of the barrier trench. Thus, in the display apparatus, the movement of hydrogen from an edge of the device substrate toward the display area can be blocked. Therefore, the degradation in the reliability of the driving circuit due to the penetration of the hydrogen can be prevented.

### CROSS-REFERENCE TO RELATED APPLICATION

This application claims the benefit of Republic of Korea Patent Application No. 10-2024-0020508, filed on Feb. 13, 2024, which is hereby incorporated by reference in its entirety.

### FIELD OF TECHNOLOGY

The present disclosure relates to a display apparatus.

### BACKGROUND

Generally, a display apparatus provides an image to a user. In the display apparatus, the characteristics of driving circuits disposed on an edge of a display area can be significantly degraded by hydrogen penetrating from a bezel area to the display area. Therefore, in the display apparatus, the quality of the image due to the deviation in the characteristics of the driving circuits can be deteriorated.

### SUMMARY

Accordingly, the present disclosure is directed to a display apparatus that substantially obviates one or more problems due to limitations and disadvantages of the related art.

An object of the present disclosure is to provide a display apparatus capable of minimizing or at least reducing the deviation in the characteristics of the driving circuits.

Another object of the present disclosure is to provide a display apparatus capable of blocking the movement of hydrogen from the bezel area toward the display area.

Additional advantages, objects, and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus comprising a device substrate. The device substrate includes a display area and a bezel area. The bezel area surrounds the display area. A plurality of inorganic insulating layers is disposed on the device substrate. The plurality of inorganic insulating layers includes an inorganic insulating material. A planarization layer is disposed on the plurality of inorganic insulating layers. The planarization layer includes an organic insulating material. A barrier line is disposed between the device substrate and the plurality of inorganic insulating layers in the bezel area. The barrier line includes a hydrogen blocking material. A barrier trench overlaps the barrier line. The barrier trench penetrates the plurality of inorganic insulating layers in the bezel area. A cover pattern is disposed between the plurality of inorganic insulating layers and the planarization layer. The cover pattern covers a side-wall of the barrier trench. A light-emitting device is disposed on the planarization layer. The light-emitting device overlaps the display area. The barrier line extends along an edge of the display area.

In another embodiment, there is provided a display apparatus comprising a device substrate. A driving circuit is disposed on a display area of the device substrate. A planarization layer is disposed on the driving circuit. The planarization layer extends onto a bezel area of the device substrate. An inorganic insulating layer is disposed between the device substrate and the planarization layer. The inorganic insulating layer overlaps the display area and the bezel area. A barrier structure is disposed on the bezel area of the device substrate. The barrier structure surrounds the display area. A light-emitting device is disposed on the planarization layer of the display area. The light-emitting device is electrically connected to the driving circuit. The barrier structure includes a barrier line and a lower cover pattern. The barrier line includes a hydrogen blocking material. The lower cover pattern is disposed on a side-wall of a lower barrier trench penetrating the inorganic insulating layer. The barrier line is disposed between the device substrate and the barrier trench in the bezel area.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view showing a circuit of a pixel area in the display apparatus according to an embodiment of the present disclosure;

FIG. 3 is a view showing a cross-section of the pixel area in the display apparatus according to the embodiment of the present disclosure;

FIG. 4 is a view taken along line I-I′ of FIG. 1 according to an embodiment of the present disclosure;

FIG. 5 is a view taken along line II-II′ of FIG. 1 according to an embodiment of the present disclosure;

FIG. 6 is a view taken along line III-III′ of FIG. 1 according to an embodiment of the present disclosure; and

FIGS. 7 to 16 are views showing the display apparatus according to another embodiment of the present disclosure.

### DETAILED DESCRIPTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below.

In addition, the same or extremely similar elements can be designated by the same reference numerals throughout the specification and in the drawings, the lengths and thickness of layers and regions can be exaggerated for convenience. It will be understood that, when a first element is referred to as being “on” a second element, although the first element can be disposed on the second element so as to come into contact with the second element, a third element can be interposed between the first element and the second element.

Here, terms such as, for example, “first” and “second” can be used to distinguish any one element with another element. However, the first element and the second element can be arbitrary named according to the convenience of those skilled in the art without departing the technical sprit of the present disclosure.

The terms used in the specification of the present disclosure are merely used in order to describe particular embodiments and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” can include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

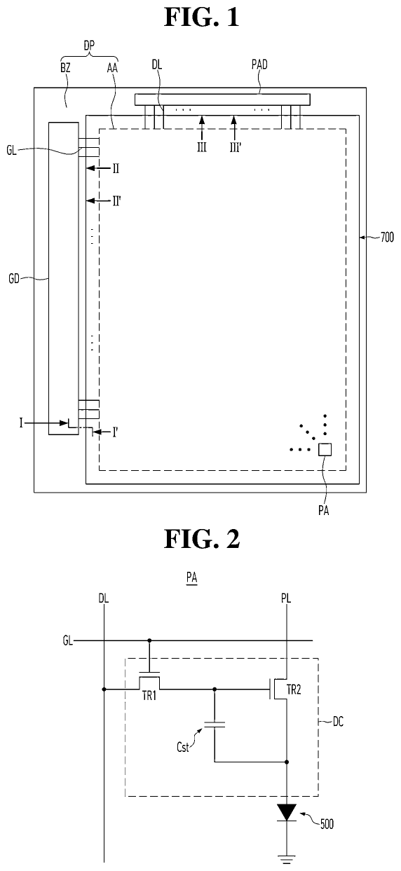

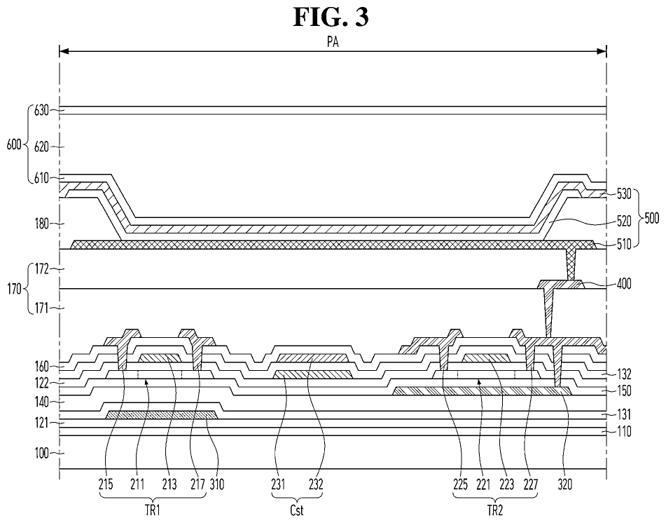

FIG. 1 is a view schematically showing a display apparatus according to an embodiment of the present disclosure. FIG. 2 is a view showing a circuit of a pixel area in the display apparatus according to an embodiment of the present disclosure. FIG. 3 is a view showing a cross-section of the pixel area in the display apparatus according to an embodiment of the present disclosure.

Referring to FIGS. 1 to 3, the display apparatus according to the embodiment of the present disclosure can include a display panel DP. The display panel DP can generate an image provided to a user. For example, a plurality of pixel areas PA can be disposed in the display panel DP. Various signals can be provided in each pixel area PA through signal wirings GL, DL and PL. For example, the signal wirings GL, DL and PL can include gate lines GL for applying a gate signal, data lines DL for applying a data signal, and power voltage supply lines PL for supplying a power voltage.

The gate lines GL can be electrically connected to a gate driver GD. The data lines DL can be electrically connected to a data driver. The gate driver GD and the data driver can be controlled by a timing controller. For example, the gate driver GD can receive clock signals, reset signals and a start signal from the timing controller, and the data driver can receive digital video data and a source timing signal from the timing controller. The power voltage supply lines PL can be electrically connected to a power unit.

Each of the pixel areas PA can realize a specific color. For example, a driving circuit DC electrically connected to a light-emitting device 500 can be disposed in each pixel area PA. The signal wirings GL, DL and PL can be electrically connected to the driving circuit DC of each pixel area PA. For example, the driving circuit DC of each pixel area PA can be electrically connected to one of the gate lines GL, one of the data lines DL, and one of the power voltage supply lines PL. The driving circuit DC of each pixel area PA can control the light-emitting device 500 of the corresponding pixel area PA according to the signal applied through the signal wirings GL, DL and PL. For example, the driving circuit DC of each pixel area PA can supply a driving current corresponding to the data signal to the light-emitting device 500 of the corresponding pixel area PA according to the gate signal. The driving current supplied by the driving circuit DC of each pixel area PA can be maintained for one frame. For example, the driving circuit DC of each pixel area PA can include a first thin film transistor TR1, a second thin film transistor TR2, and a storage capacitor Cst.

The first thin film transistor TR1 of each pixel area PA can transmit the data signal to the second thin film transistor TR2 of the corresponding pixel area PA according to the gate signal. For example, the first thin film transistor TR1 of each pixel area PA can function as a switching thin film transistor. The first thin film transistor TR1 of each pixel area PA can include a first semiconductor pattern 211, a first gate electrode 213, a first drain electrode 215, and a first source electrode 217. For example, the first gate electrode 213 of each pixel area PA can be electrically connected to the corresponding gate line GL, and the first drain electrode 215 of each pixel area PA can be electrically connected to the corresponding date line DL.

The first semiconductor pattern 211 can include a semiconductor material. For example, the first semiconductor pattern 211 can include an oxide semiconductor, such as IGZO. The first semiconductor pattern 211 can include a first drain region, a first channel region, and a first source region. The first channel region can be disposed between the first drain region and the first source region. The first drain region and the first source region can have a smaller resistance than the first channel region. For example, the first drain region and the first source region can include a conductive region of an oxide semiconductor. The first channel region can be a region of an oxide semiconductor, which is not conductorized.

The first gate electrode 213 can be disposed on a portion of the first semiconductor pattern 211. For example, the first gate electrode 213 can overlap the first channel region of the first semiconductor pattern 211. The first drain region and the first source region of the first semiconductor pattern 211 can be disposed outside the first gate electrode 213. The first gate electrode 213 can include a conductive material. For example, the first gate electrode 213 can include a metal, such as aluminum (Al), chrome (Cr), copper (Cu), molybdenum (Mo), titanium (Ti) and tungsten (W). The first gate electrode 213 can be spaced apart from the first semiconductor pattern 211. The first gate electrode 213 can be insulated from the first semiconductor pattern 211. For example, the first drain region of the first semiconductor pattern 211 can be electrically connected to the first source region of the first semiconductor pattern 211 according to a signal applied to the first gate electrode 213.

The first drain electrode 215 can include a conductive material. For example, the first drain electrode 215 can include a metal, such as aluminum (Al), chrome (Cr), copper (Cu), molybdenum (Mo), titanium (Ti) and tungsten (W). The first drain electrode 215 can include a different material from the first gate electrode 213. For example, the first drain electrode 215 can be disposed on a different layer from the first gate electrode 213. The first drain electrode 215 can be electrically connected to the first drain region of the first semiconductor pattern 211. The first drain electrode 215 can be insulated from the first gate electrode 213.

The first source electrode 217 can include a conductive material. For example, the first source electrode 217 can include a metal, such as aluminum (Al), chrome (Cr), copper (Cu), molybdenum (Mo), titanium (Ti) and tungsten (W). The first source electrode 217 can include a different material from the first gate electrode 213. The first source electrode 217 can be disposed on a different layer from the first gate electrode 213. For example, the first source electrode 217 can be disposed on a same layer as the first drain electrode 215. The first source electrode 217 can include a same material as the first drain electrode 215. The first source electrode 217 can be formed by a same process as the first drain electrode 215. For example, the first source electrode 217 can be formed simultaneously with the first drain electrode 215. The first source electrode 217 can be electrically connected to the first source region of the first semiconductor pattern 211. The first source electrode 217 can be insulated from the first gate electrode 213. The first source electrode 217 can be spaced apart from the first drain electrode 215.

The second thin film transistor TR2 of each pixel area PA can generate the driving current corresponding to the data signal. For example, the second thin film transistor TR2 of each pixel area PA can function as a driving thin film transistor. The second thin film transistor TR2 of each pixel area PA can include a second semiconductor pattern 221, a second gate electrode 223, a second drain electrode 225, and a second source electrode 227. For example, the second gate electrode 223 of each pixel area PA can be electrically connected to the first source electrode 213 of the corresponding pixel area PA, and the second drain electrode 225 of each pixel area PA can be electrically connected to the corresponding power voltage supply line PL.

The second semiconductor pattern 221 can include a semiconductor material. For example, the second semiconductor pattern 221 can include an oxide semiconductor, such as IGZO. The second semiconductor pattern 221 can include a second drain region, a second channel region and a second source region. The second channel region can be disposed between the second drain region and the second source region. The second drain region and the second source region can have a smaller resistance than the second channel region. For example, the second drain region and the second source region can include a conductive region of an oxide semiconductor. The second channel region can be a region of an oxide semiconductor, which is not conductorized.

The second semiconductor pattern 221 can include a same material as the first semiconductor pattern 211. The second semiconductor pattern 221 can be disposed on a same layer as the first semiconductor pattern 211. The second semiconductor pattern 221 can be formed by a same process as the first semiconductor pattern 211. For example, the second semiconductor pattern 221 can be formed simultaneously with the first semiconductor pattern 211.

The second gate electrode 223 can be disposed on a portion of the second semiconductor pattern 221. For example, the second gate electrode 223 can overlap the second channel region of the second semiconductor pattern 221. The second drain region and the second source region of the second semiconductor pattern 221 can be disposed outside the second gate electrode 223. The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be spaced apart from the second semiconductor pattern 221. The second gate electrode 223 can be insulated from the second semiconductor pattern 221. For example, the second drain region of the second semiconductor pattern 221 can have an electrical conductivity according to a voltage applied to the second gate electrode 223.

The second gate electrode 223 can include a same material as the first gate electrode 213. The second gate electrode 223 can be disposed on a same layer as the first gate electrode 213. The second gate electrode 223 can be formed by a same process as the first gate electrode 213. For example, the second gate electrode 223 can be formed simultaneously with the first gate electrode 213.

The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can include a different material from the second gate electrode 223. For example, the second drain electrode 225 can be disposed on a different layer from the second gate electrode 223. The second drain electrode 225 can be electrically connected to the second drain region of the second semiconductor pattern 221. The second drain electrode 225 can be insulated from the second gate electrode 223.

The second drain electrode 225 can be disposed on a same layer as the first drain electrode 215. The second drain electrode 225 can include a same material as the first drain electrode 215. The second drain electrode 225 can be formed by a same process as the first drain electrode 215. For example, the second drain electrode 225 can be formed simultaneously with the first drain electrode 215.

The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can include a different material from the second gate electrode 223. The second source electrode 227 can be disposed on a different layer from the second gate electrode 223. For example, the second source electrode 227 can be disposed on a same layer as the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225. The second source electrode 227 can be electrically connected to the second source region of the second semiconductor pattern 221. The second source electrode 227 can be insulated from the second gate electrode 223. The second source electrode 227 can be spaced apart from the second drain electrode 225.

The storage capacitor Cst of each pixel area PA can maintain a signal applied to the second gate electrode 223 of the corresponding pixel area PA for one frame. For example, the storage capacitor Cst of each pixel area PA can be electrically connected between the second gate electrode 223 and the second source electrode 227 of the corresponding pixel area PA. The storage capacitor Cst of each pixel area PA can have a stacked structure of capacitor electrodes 231 and 232. For example, the storage capacitor Cst of each pixel area PA can have a stacked structure of a first capacitor electrode 231 and a second capacitor electrode 232. The first capacitor electrode 231 of each pixel area PA can be electrically connected to the second gate electrode 223 of the corresponding pixel area PA. The second capacitor electrode 232 of each pixel area PA can be electrically connected to the second source electrode 227 of the corresponding pixel area PA.

At least one of the capacitor electrodes 231 and 232 of the storage capacitor Cst in each pixel area PA can be formed by using a process of forming the first thin film transistor TR1 and the second thin film transistor TR2 of the corresponding pixel area PA. For example, the first capacitor electrode 231 of each pixel area PA can be disposed on a same layer as the second gate electrode 223 of the corresponding pixel area PA. The first capacitor electrode 231 of each pixel area PA can include a same material as the second gate electrode 223 of the corresponding pixel area PA. The first capacitor electrode 231 of each pixel area PA can be formed by a same process as the second gate electrode 223 of the corresponding pixel area PA. For example, the first capacitor electrode 231 of each pixel area PA can be formed simultaneously with the second gate electrode 223 of the corresponding pixel area PA. Thus, in the display apparatus according to the embodiment of the present disclosure, a process of forming the driving circuit DC in each pixel area PA can be simplified.

The second capacitor electrode 232 of each pixel area PA can be disposed on a different layer from the first gate electrode 213, the first drain electrode 215, the first source electrode 217, the second gate electrode 223, the second drain electrode 225 and the second source electrode 227 of the corresponding pixel area PA. For example, the second capacitor electrode 232 of each pixel area PA can include a different material from the first gate electrode 213, the first drain electrode 215, the first source electrode 217, the second gate electrode 223, the second drain electrode 225 and the second source electrode 227 of the corresponding pixel area PA.

The driving circuit DC of each pixel area PA can be disposed on a device substrate 100. For example, the device substrate 100 can support the first thin film transistor TR1, the second thin film transistor TR2 and the storage capacitor Cst of each pixel area PA. The device substrate 100 can include an insulating material. For example, the device substrate 100 can include glass or plastic.

A plurality of insulating layers 110, 121, 122, 131, 132, 140, 150, 160, 170 and 180 for preventing or at least reducing unnecessary electrical connection of the driving circuit DC in each pixel area PA can be disposed on the device substrate 100. For example, a lower buffer layer 110, a lower gate insulating layer 121, an upper gate insulating layer 122, a lower interlayer insulating layer 131, a first upper interlayer insulating layer 132, a separation insulating layer 140, an upper buffer layer 150, a second upper interlayer insulating layer 160, a planarization layer 170, and a bank insulating layer 180 can be disposed on the device substrate 100.

The lower buffer layer 110 can be disposed on the device substrate 100. The lower buffer layer 110 can prevent or at least reduce the pollution due to the device substrate 100 in a process of forming the driving circuit DC of each pixel area PA. For example, an upper surface of the device substrate 100 toward the driving circuit DC of each pixel area PA can be covered by the lower buffer layer 110. The driving circuit DC of each pixel area PA can be disposed on the lower buffer layer 110. The lower buffer layer 110 can include an insulating material. For example, the lower buffer layer 110 can be an inorganic insulating layer including an inorganic insulating material, such as silicon oxide (SiOx) and silicon nitride (SiNx).

The lower gate insulating layer 121, the lower interlayer insulating layer 131, the separation insulating layer 140 and the upper buffer layer 150 can be sequentially stacked on the lower buffer layer 110. For example, the lower interlayer insulating layer 131 can be disposed on the lower gate insulating layer 121, the separation insulating layer 140 can be disposed on the lower interlayer insulating layer 131, and the upper buffer layer 150 can be disposed on the separation insulating layer 140. The lower gate insulating layer 121, the lower interlayer insulating layer 131, the separation insulating layer 140 and the upper buffer layer 150 can include an insulating material. For example, the lower gate insulating layer 121, the lower interlayer insulating layer 131, the separation insulating layer 140 and the upper buffer layer 150 can be an inorganic insulating layer including an inorganic insulating material, such as silicon oxide (SiOx) and silicon nitride (SiNx). The lower gate insulating layer 121, the lower interlayer insulating layer 131, the separation insulating layer 140 and the upper buffer layer 150 can include a different material from each other.

Device light-blocking patterns 310 and 320 can be disposed between the lower buffer layer 110 and the upper buffer layer 150 of each pixel area PA. The device light-blocking patterns 310 and 320 can include a material absorbing or reflecting light. For example, the device light-blocking patterns 310 and 320 can include a metal. The device light-blocking patterns 310 and 320 of each pixel area PA can include a first light-blocking pattern 310 overlapping with the first semiconductor pattern 211 of the corresponding pixel area PA and a second light-blocking pattern 320 overlapping with the second semiconductor pattern 221 of the corresponding pixel area PA. For example, the first light-blocking pattern 310 of each pixel area PA can be disposed between the device substrate 100 and the first semiconductor pattern 211 of the corresponding pixel area PA, and the second light-blocking pattern 320 of each pixel area PA can be disposed between the device substrate 100 and the second semiconductor pattern 221 of the corresponding pixel area PA. Thus, in the display apparatus according to the embodiment of the present disclosure, light travelling toward the first semiconductor pattern 211 of each pixel area PA passing through the device substrate 100 can be blocked by the first light-blocking pattern 310 of the corresponding pixel area PA, and light travelling toward the second semiconductor pattern 221 of each pixel area PA passing through the device substrate 100 can be blocked by the second light-blocking pattern 320 of the corresponding pixel area PA. Therefore, in the display apparatus according to the embodiment of the present disclosure, change in characteristics of the first thin film transistor TR1 and the second thin film transistor TR2 in each pixel area PA due to external light introduced through the device substrate 100 can be prevented.

The first light-blocking pattern 310 and the second light-blocking pattern 320 can include a hydrogen blocking material. Here, the “hydrogen blocking material” can refer to a material capable of blocking the movement of hydrogen. For example, the “hydrogen blocking material” can include a material capable of adsorbing hydrogen, such as titanium (Ti). Thus, in the display apparatus according to the embodiment of the present disclosure, the movement of hydrogen contained in the lower buffer layer 110, the lower gate insulating layer 121, the lower interlayer insulating layer 131, the separation insulating layer 140 and the upper buffer layer 150, which are an inorganic insulating layer toward the first semiconductor pattern 211 and the second semiconductor pattern 221 of each pixel area PA can be blocked by the first light-blocking pattern 310 and the second light-blocking pattern 320 of the corresponding pixel area PA. That is, in the display apparatus according to the embodiment of the present disclosure, the change in the characteristics of the first semiconductor pattern 211 and the second semiconductor pattern 221 in each pixel area PA due to hydrogen can be prevented. And, in the display apparatus according to the embodiment of the present disclosure, the change in the characteristics of the driving circuit DC in each pixel area PA due to hydrogen can be prevented or at least reduced. Therefore, in the display apparatus according to the embodiment of the present disclosure, the reliability of the driving circuit DC in each pixel area PA can be improved.

A specific voltage can be applied to the first light-blocking pattern 310 of each pixel area PA. For example, the first light-blocking pattern 310 of each pixel area PA can be electrically connected to the first gate electrode 213 of the corresponding pixel area PA. Thus, in the display apparatus according to the embodiment of the present disclosure, the first light-blocking pattern 310 of each pixel area PA can function as a sub-gate electrode of the first thin film transistor TR1 in the corresponding pixel area PA. The first semiconductor pattern 211 of each pixel area PA can be disposed between the first light-blocking pattern 310 and the first gate electrode 213 of the corresponding pixel area PA. That is, in the display apparatus according to the embodiment of the present disclosure, a first channel of the first semiconductor pattern 211 can be formed by a voltage applied to the first gate electrode 213 of the corresponding pixel area PA and a voltage applied to the first light-blocking pattern 310 of the corresponding pixel area PA. Therefore, in the display apparatus according to the embodiment of the present disclosure, the response speed of the first thin film transistor TR1 in each pixel area PA can be increased.

A specific voltage can be applied to the second light-blocking pattern 320 of each pixel area PA. For example, the second light-blocking pattern 320 of each pixel area PA can be electrically connected to the second drain electrode 225 of the corresponding pixel area PA. That is, in the display apparatus according to the embodiment of the present disclosure, the power voltage can be supplied to the second light-blocking pattern 320 of each pixel area PA. Thus, in the display apparatus according to the embodiment of the present disclosure, the deviation in the driving current generated by the second thin film transistor TR2 of each pixel area PA due to a voltage applied to the second light-blocking pattern 320 of the corresponding pixel area PA can be prevented or at least reduced. Therefore, in the display apparatus according to the embodiment of the present disclosure, the change in the characteristics of the second thin film transistor TR2 in each pixel area PA due to the external light introduced through the device substrate 100 can be effectively prevented.

The second light-blocking pattern 320 of each pixel area PA can be disposed on a different layer from the first light-blocking pattern 310 of the corresponding pixel area PA. For example, the first light-blocking pattern 310 of each pixel area PA can be disposed between the lower gate insulating layer 121 and the lower interlayer insulating layer 131, and the second light-blocking pattern 320 of each pixel area PA can be disposed between the separation insulating layer 140 and the upper buffer layer 150. The first semiconductor pattern 211 and the second semiconductor pattern 221 of each pixel area PA can be disposed on the upper buffer layer 150. Thus, in the display apparatus according to the embodiment of the present disclosure, a distance between the second light-blocking pattern 320 and the second semiconductor pattern 221 in each pixel area PA can be smaller than a distance between the first light-blocking pattern 310 and the first semiconductor pattern 211 in the corresponding pixel area PA. The amount of change in the effective gate voltage of a thin film transistor disposed on a conductive pattern can be determined by the following equation. Here, ΔVeff represents the amount of change in the effective gate voltage, ΔVGAT represents the amount of change in a voltage applied to the gate electrode, C1 represents capacitance of the parasitic capacitor formed between the conductive pattern and a semiconductor pattern of the corresponding thin film transistor, C2 represents capacitance of the parasitic capacitor formed between the semiconductor pattern and the gate electrode of the corresponding thin film transistor, and CACT represents capacitance of the parasitic capacitor formed by a voltage applied to a drain region and a source region of the corresponding thin film transistor.

$$Δ {V}_{eff} = \frac{C 2}{C 2 + {C}_{A C T} + C 1} \times Δ {V}_{G A T}$$

Capacitance of a capacitor is inversely proportional to a distance between conductors constituting the corresponding capacitor. Thus, in the display apparatus according to the embodiment of the present disclosure, the capacitance of the parasitic capacitor formed between the second light-blocking pattern 320 and the second semiconductor pattern 221 of each pixel area PA can be larger than the capacitance of the parasitic capacitor formed between the first light-blocking pattern 310 and the first semiconductor pattern 211 of the corresponding pixel area PA. And, in the display apparatus according to the embodiment of the present disclosure, the amount of change in the effective gate voltage of the second thin film transistor T2 in each pixel area PA can be smaller than the amount of change in the effective gate voltage of the first thin film transistor T1 in the corresponding pixel area PA. In a general thin film transistor, the amount of change in the effective gate voltage is inversely proportional to an S-factor of the corresponding thin film transistor. Here, the S-factor of the thin film transistor means an inverse ratio of the amount of change in the current generated by the corresponding thin film transistor and the amount of change in the voltage applied to the gate electrode of the corresponding thin film transistor. Therefore, in the display apparatus according to the embodiment of the present disclosure, the second thin film transistor TR2 in each pixel area PA can have a relatively large S-factor. That is, in the display apparatus according to the embodiment of the present disclosure, the amount of change in the driving current generated by the second thin film transistor TR2 of each pixel area PA according to change in the voltage applied to the second gate electrode 223 of the corresponding pixel area PA can be reduced, and the occurrence of stains due to deviation of luminance can be prevented.

The upper gate insulating layer 122 can be disposed on the upper buffer layer 150. The first gate electrode 213 of each pixel area PA can be insulated from the first semiconductor pattern 211 of the corresponding pixel area PA by the upper gate insulating layer 122. The second gate electrode 223 of each pixel area PA can be insulated from the second semiconductor pattern 221 of the corresponding pixel area PA by the upper gate insulating layer 122. For example, the upper gate insulating layer 122 can cover the first semiconductor pattern 211 and the second semiconductor pattern 221 of each pixel area PA. The first gate electrode 213 and the second gate electrode 223 of each pixel area PA can be disposed on the upper gate insulating layer 122. The upper gate insulating layer 122 can include an insulating material. For example, the upper gate insulating layer 122 can be an inorganic insulating layer including an inorganic insulating material, such as silicon oxide (SiOx) and silicon nitride (SiNx).

The first upper interlayer insulating layer 132 can be disposed on the upper gate insulating layer 122. For example, the first gate electrode 213 and the second gate electrode 223 of each pixel area PA can be covered by the first upper interlayer insulating layer 132. The first upper interlayer insulating layer 132 can include an insulating material. For example, the first upper interlayer insulating layer 132 can be an inorganic insulating layer including an inorganic insulating material, such as silicon oxide (SiOx) and silicon nitride (SiNx).

The first upper interlayer insulating layer 132 can extend between the first capacitor electrode 231 and the second capacitor electrode 232 of each pixel area PA. For example, the first capacitor electrode 231 of each pixel area PA can be covered by the first upper interlayer insulating layer 132. The second capacitor electrode 232 of each pixel area PA can be disposed on the first upper interlayer insulating layer 132.

The second upper interlayer insulating layer 160 can be disposed on the first upper interlayer insulating layer 132. The first drain electrode 215 and the first source electrode 217 of each pixel area PA can be insulated from the first gate electrode 213 of the corresponding pixel area PA by the first upper interlayer insulating layer 132 and the second upper interlayer insulating layer 160. The second drain electrode 225 and the second source electrode 227 of each pixel area PA can be insulated from the second gate electrode 223 of the corresponding pixel area PA by the first upper interlayer insulating layer 132 and the second upper interlayer insulating layer 160. For example, the first drain electrode 215, the first source electrode 217, the second drain electrode 225, and the second source electrode 227 of each pixel area PA can be disposed on the second upper interlayer insulating layer 160. The second capacitor electrode 232 of each pixel area PA can be covered by the second upper interlayer insulating layer 160. The second upper interlayer insulating layer 160 can include an insulating material. For example, the second upper interlayer insulating layer 160 can be an inorganic insulating layer including an inorganic insulating material.

The planarization layer 170 can be disposed on the second upper interlayer insulating layer 160. The planarization layer 170 can remove a thickness difference due to the driving circuit DC of each pixel area PA. For example, an upper surface of the planarization layer 170 opposite to the device substrate 100 can be flat. The first drain electrode 215, the first source electrode 217, the second drain electrode 225, the second source electrode 227 of each pixel area PA can be covered by the planarization layer 170. The planarization layer 170 can include an insulating material. The planarization layer 170 can include a different material from the second upper interlayer insulating layer 160. The planarization layer can have a material having a relative higher fluidity than the second upper interlayer insulating layer 160. For example, the planarization layer 170 can be an organic insulating layer including an organic insulating material.

The planarization layer 170 can have a multi-layer structure. For example, the planarization layer 170 can have a stacked structure of a lower planarization layer 171 and an upper planarization layer 172. The upper planarization layer 172 can be disposed on the lower planarization layer 171. For example, the first drain electrode 215, the first source electrode 217, the second drain electrode 225, the second source electrode 227 of each pixel area PA can be covered by the lower planarization layer 171. The upper planarization layer 172 can include a different material from the lower planarization layer 171. Thus, in the display apparatus according to the embodiment of the present disclosure, a thickness difference due to the driving circuit DC of each pixel area PA can be effectively removed.

The light-emitting device 500 of each pixel area PA can be disposed on the upper planarization layer 172. The light-emitting device 500 of each pixel area PA can emit light displaying a specific color. For example, the light-emitting device 500 of each pixel area PA can include a first electrode 510, a light-emitting layer 520, and a second electrode 530, which are sequentially stacked on the upper planarization layer 172 of the corresponding pixel area PA.

The first electrode 510 can include a conductive material. The first electrode 510 can include a material having a high reflectance. For example, the first electrode 510 can include a metal, such as aluminum (Al) and silver (Ag). The first electrode 510 can have a multi-layer structure. For example, the first electrode 510 can have a structure in which a reflective electrode made of a metal is disposed between transparent electrodes made of a transparent conductive material, such as ITO and IZO.

The light-emitting layer 520 can generate light having luminance corresponding to a voltage difference between the first electrode 510 and the second electrode 530. For example, the light-emitting layer 520 can include at least one emission material layer (EML). The emission material layer can include an organic emission material, an inorganic emission material or a hybrid emission material. For example, the display apparatus according to the embodiment of the present disclosure can be an organic light-emitting display apparatus including an organic emission material.

The light-emitting layer 520 can have a multi-layer structure. For example, the light-emitting layer 520 can include at least one of a hole injection layer (HIL), a hole transport layer (HTL), an electron transport layer (ETL), and an electron injection layer (EIL). Thus, in the display apparatus according to the embodiment of the present disclosure, the emission efficiency of the light-emitting layer 520 can be improved.

The second electrode 530 can include a conductive material. The second electrode 530 can include a different material from the first electrode 510. A transmittance of the second electrode 530 can be greater than a transmittance of the first electrode 510. For example, the second electrode 530 can be a transparent electrode made of a transparent conductive material, such as ITO and IZO. Thus, in the display apparatus according to the embodiment of the present disclosure, the light generated by the light-emitting layer 520 can be emitted through the second electrode 530. The second electrode 530 can have a work-function smaller than the first electrode 510. For example, the first electrode 510 can function as anode electrode, and the second electrode 530 can function as cathode electrode.

The bank insulating layer 180 can be disposed on the planarization layer 170. The bank insulating layer 180 can define an emission area in each pixel area PA. A region disposed between adjacent emission areas can define as a non-emission area. For example, the bank insulating layer 180 can overlap the non-emission area. The first electrode 510 of each pixel area PA can be insulated from the first electrode 510 of adjacent pixel area PA by the bank insulating layer 180. For example, an edge of the first electrode 510 in each pixel area PA can be covered by the bank insulating layer 180. The first electrode 510 of each pixel area PA can be partially exposed by the bank insulating layer 180. The light-emitting layer 520 and the second electrode 530 of each pixel area PA can be stacked on a portion of the corresponding first electrode 510 exposed by the bank insulating layer 180. For example, the first electrode 510, the light-emitting layer 520 and the second electrode 520 of each pixel area PA can be stacked on the emission area defined in the corresponding pixel area PA by the bank insulating layer 180. The bank insulating layer 180 can include an insulating material. For example, the bank insulating layer 180 can include an organic insulating material. The bank insulating layer 180 can include a different material from the planarization layer 170.

The first electrode 510 of each pixel area PA can be electrically connected to the driving circuit DC of the corresponding pixel area PA. For example, the first electrode 510 of each pixel area PA can be in direct contact with the second source electrode 227 of the corresponding pixel area PA. The electrical connection between the second source electrode 227 and the first electrode 510 in each pixel area PA can be performed in the non-emission area. Thus, in the display apparatus according to the embodiment of the present disclosure, the deviation in the location of the first electrode 510 in the emission area of each pixel area PA can be minimized. For example, a portion of the first electrode 510 overlapping with the emission area of each pixel area PA can be in direct contact with the upper surface of the planarization layer 170. Therefore, in the display apparatus according to the embodiment of the present disclosure, the deviation in the luminance according to the generating location of the light emitted from the emission area of each pixel area PA can be prevented.

Intermediate electrodes 400 electrically connecting the light-emitting device 500 of each pixel area PA to the driving circuit DC of the corresponding pixel area PA can be disposed between the lower planarization layer 171 and the upper planarization layer 172. The intermediate electrodes 400 can include a conductive material. For example, the intermediate electrodes 400 can include a metal, such as aluminum (Al), chrome (Cr), copper (Cu), molybdenum (Mo), titanium (Ti) and tungsten (W). Each of the intermediate electrodes 400 can be in direct contact with the second source electrode 227 and the first electrode 510 in one of the pixel areas PA. For example, the first electrode 510 of each pixel area PA can be in contact with one of the intermediate electrodes 400 by penetrating the upper planarization layer 172, and each of the intermediate electrodes 400 can be in contact with the second source electrode 227 in one of the pixel areas PA by penetrating the lower planarization layer 171. Thus, in the display apparatus according to the embodiment of the present disclosure, the first electrode 510 of each pixel area PA can be stably connected to the second source electrode 227 of the corresponding pixel area PA. Therefore, in the display apparatus according to the embodiment of the present disclosure, the reliability for the electrical connections between the driving circuit DC and the light-emitting device 500 in each pixel area PA can be improved.

The light emitted from the light-emitting device 500 of each pixel area PA can display a different color from the light emitted from the light-emitting device 500 of adjacent pixel area PA. For example, the light-emitting layer 520 of each pixel area PA can be spaced apart from the light-emitting layer 520 of adjacent pixel area PA. The light-emitting layer 520 of each pixel area PA can include a different material from the light-emitting layer 520 of adjacent pixel area PA. For example, the light-emitting layer 520 of each pixel area PA can have a stacked structure different from the light-emitting layer 520 of adjacent pixel area PA. The light-emitting layer 520 of each pixel area PA can include an end portion disposed on the bank insulating layer 180.

A voltage applied to the second electrode 530 of each pixel area PA can be a same as a voltage applied to the second electrode 530 of adjacent pixel area PA. For example, the second electrode 530 of each pixel area PA can be electrically connected to the second electrode 530 of adjacent pixel area PA. The second electrode 530 of each pixel area PA can include a same material as the second electrode 530 of adjacent pixel area PA. The second electrode 530 of each pixel area PA can be formed by a same process as the second electrode 530 of adjacent pixel area PA. For example, the second electrode 530 of each pixel area PA can be formed simultaneously with the second electrode 530 of adjacent pixel area PA. The second electrode 530 of each pixel area PA can be in direct contact with the second electrode 530 of adjacent pixel area PA. Thus, in the display apparatus according to the embodiment of the present disclosure, a process of forming the second electrode 530 of each pixel area PA can be simplified. And, in the display apparatus according to the embodiment of the present disclosure, the luminance of the light generated by the light-emitting layer 520 in each pixel area PA can be adjusted by the data signal applied to the driving circuit DC in the corresponding pixel area PA.

An encapsulation unit 600 can be disposed on the light-emitting device 500 of each pixel area PA. The encapsulation unit 600 can prevent the damage of the light-emitting devices 500 due to external moisture and impact. The encapsulation unit 600 can have a multi-layer structure. For example, the encapsulation unit 600 can include a first encapsulating layer 610, a second encapsulating layer 620 and a third encapsulating layer 630, which are sequentially stacked. The first encapsulating layer 610, the second encapsulating layer 620 and the third encapsulating layer 630 can include an insulating material. The second encapsulating layer 620 can include a different material from the first encapsulating layer 610 and the third encapsulating layer 630. For example, the first encapsulating layer 610 and the third encapsulating layer 630 can be an inorganic insulating layer including an inorganic insulating material, and the second encapsulating layer 620 can be an organic insulating layer including an organic insulating material. A thickness difference due to the light-emitting device 500 of each pixel area PA can be removed by the second encapsulating layer 620. The second encapsulating layer 620 can have a larger thickness than the first encapsulating layer 610 and the third encapsulating layer 630. For example, an upper surface of the encapsulation unit 600 opposite to the device substrate 100 can be flat. Thus, in the display apparatus according to the embodiment of the present disclosure, the damage of the light-emitting devices 500 due to the external moisture and impact can be effectively prevented.

The display panel DP can include a display area AA in which the pixel areas PA are disposed, and a bezel area BZ being disposed outside the pixel areas PA. The bezel area BZ can have a shape extending along an edge of the display area AA. For example, the display area AA can be surrounded by the bezel area BZ. The gate driver GD, the data driver, the timing controller and the power unit can be disposed outside the display area AA. For example, each of the signal wiring GL, DL and PL can include a region disposed on the bezel area BZ.

At least one of the gate driver GD, the data driver, the timing controller and the power unit can be disposed on the bezel area BZ. For example, the display apparatus according to the embodiment of the present disclosure can be a GIP (Gate In Panel) type display apparatus in which the gate driver GD is formed on the bezel area BZ of the device substrate 100.

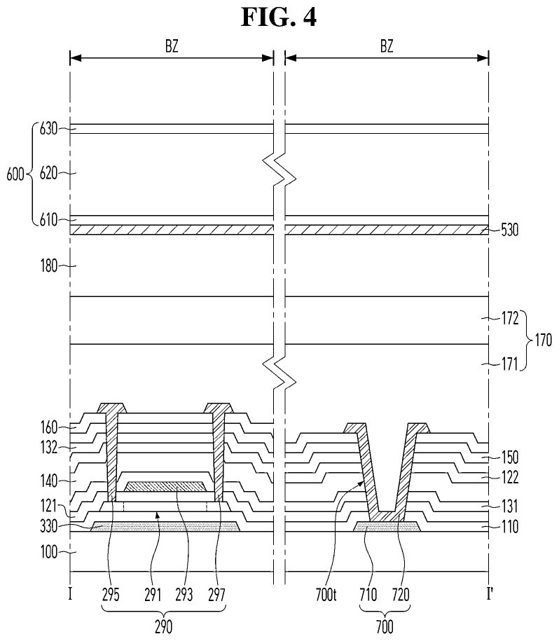

As shown in FIG. 4, the gate driver GD formed on the bezel area BZ can include at least one circuit thin film transistor 290. The circuit thin film transistor 290 can function as a switching thin film transistor. For example, the circuit thin film transistor 290 can include a circuit semiconductor pattern 291, a circuit gate electrode 293, a circuit drain electrode 295 and a circuit source electrode 297. The insulating layers 110, 121, 122, 131, 132, 140, 150, 160, 170 and 180 disposed on the display area AA of the device substrate 100 can extend onto the bezel area BZ of the device substrate 100. For example, the circuit semiconductor pattern 291, the circuit gate electrode 293, the circuit drain electrode 295 and the circuit source electrode 297 of the circuit thin film transistor 290 can be disposed between the lower buffer layer 110 and the lower planarization layer 171 of the bezel area BZ.

The circuit semiconductor pattern 291 can include a semiconductor material. The circuit semiconductor pattern 291 can include a material different from the first semiconductor pattern 211 and the second semiconductor pattern 221 of each pixel area PA. For example, the circuit semiconductor pattern 291 can include low-temperature poly-Si (LTPS). The circuit semiconductor pattern 291 can be disposed on a different layer from the first semiconductor pattern 211 and the second semiconductor pattern 221 of each pixel area PA. For example, the circuit semiconductor pattern 291 can be disposed between the lower buffer layer 110 and the lower gate insulating layer 121 of the bezel area BZ.

The circuit semiconductor pattern 291 can include a circuit drain region, a circuit channel region, and a circuit source region. The circuit channel region can be disposed between the circuit drain region and the circuit source region. The circuit drain region and the circuit source region can have a smaller resistance than the circuit channel region. For example, the circuit drain region and the circuit source region can include conductive impurities. The circuit channel region can be a region, which is not doped with conductive impurities.

The circuit gate electrode 293 can be spaced apart from the circuit semiconductor pattern 291. The circuit gate electrode 293 can be insulated from the circuit semiconductor pattern 291. The circuit gate electrode 293 can be disposed on a different layer from the first gate electrode 213 and the second gate electrode 223 of each pixel area PA. For example, the circuit gate electrode 293 can be disposed between the lower gate insulating layer 121 and the lower interlayer insulating layer 131 of the bezel area BZ. The circuit gate electrode 293 can overlap the circuit channel region of the circuit semiconductor pattern 291. For example, the circuit drain region and the circuit source region of the circuit semiconductor pattern 291 can be disposed outside the circuit gate electrode 293. The circuit gate electrode 293 can include a conductive material. For example, the circuit gate electrode 293 can include a metal, such as aluminum (Al), chrome (Cr), copper (Cu), molybdenum (Mo), titanium (Ti) and tungsten (W). The circuit drain region of the circuit semiconductor pattern 291 can be electrically connected to the circuit source region of the circuit semiconductor pattern 291 according to a voltage applied to the circuit gate electrode 293.

The circuit drain electrode 295 can include a conductive material. For example, the circuit drain electrode 295 can include a metal, such as aluminum (Al), chrome (Cr), copper (Cu), molybdenum (Mo), titanium (Ti) and tungsten (W). The circuit drain electrode 295 can include a different material from the circuit gate electrode 293. The circuit drain electrode 295 can be disposed on a different layer from the circuit gate electrode 293. The circuit drain electrode 295 can be disposed on a same layer as the first drain electrode 215 and the second drain electrode 225 of each pixel area PA. For example, the circuit drain electrode 295 can be disposed between the second upper interlayer insulating layer 160 and the lower planarization layer 171 of the bezel area BZ. The circuit drain electrode 295 can include a same material as the first drain electrode 215 and the second drain electrode 225 of each pixel area PA. The circuit drain electrode 295 can be formed by a same process as the first drain electrode 215 and the second drain electrode 225 of each pixel area PA. For example, the circuit drain electrode 295 can be formed simultaneously with the first drain electrode 215 and the second drain electrode 225 of each pixel area PA. The circuit drain electrode 295 can be electrically connected to the circuit drain region of the circuit semiconductor pattern 291. The circuit drain electrode 295 can be insulated from the circuit gate electrode 293.

The circuit source electrode 297 can include a conductive material. For example, the circuit source electrode 297 can include a metal such as aluminum (Al), chrome (Cr), copper (Cu), molybdenum (Mo), titanium (Ti) and tungsten (W). The circuit source electrode 297 can include a different material from the circuit gate electrode 293. The circuit source electrode 297 can be disposed on a different layer from the circuit gate electrode 293. The circuit source electrode 297 can be disposed on a same layer as the circuit drain electrode 295. For example, the circuit source electrode 297 can be disposed between the second upper interlayer insulating layer 160 and the lower planarization layer 171 of the bezel area BZ. The circuit source electrode 297 can include a same material as the circuit drain electrode 295. The circuit source electrode 297 can be formed by a same process as the circuit drain electrode 295. For example, the circuit source electrode 297 can be formed simultaneously with the circuit drain electrode 295. The circuit source electrode 297 can be electrically connected to the circuit source region of the circuit semiconductor pattern 291. The circuit source electrode 297 can be spaced apart from the circuit drain electrode 295.

A circuit light-blocking pattern 330 can be disposed between the device substrate 100 and the lower buffer layer 110 in the bezel area BZ. The circuit light-blocking pattern 330 can include a material absorbing or reflecting light. For example, the circuit light-blocking pattern 330 can include a metal. The circuit light-blocking pattern 330 can overlap the circuit semiconductor pattern 291. Thus, in the display apparatus according to the embodiment of the present disclosure, the light traveling toward the circuit semiconductor pattern 291 passing through the device substrate 100 can be blocked by the circuit light-blocking pattern 330. Therefore, in the display apparatus according to the embodiment of the present disclosure, change in characteristics of the circuit thin film transistor 290 due to the external light introduced through the device substrate 100 can be prevented.

As shown in FIGS. 1 to 4, a pad area PAD in which external signal is applied can be disposed in the bezel area BZ. The data driver, the timing controller and the power unit disposed outside the display panel DP can apply a signal through the pad area PAD. For example, the data lines DL can be electrically connected to the data driver through the pad area PAD. The pad area PAD can be disposed on a side of the display area AA. A side of the display area AA toward the pad area PAD can be different from a side of the display area AA toward the gate driver GD. Thus, in the display apparats according to the embodiment of the present disclosure, a size of the bezel area BZ due to a space between the gate lines GL between the gate driver GD and the display area AA and a space between the signal wirings DL and PL between the pad area PAD and the display area AA can be minimized.

A barrier structure 700 can be disposed on the bezel area BZ of the device substrate 100. The barrier structure 700 can block the movement of hydrogen contained in the plurality of inorganic insulating layers that are disposed between the device substrate 100 and the lower planarization layer 171 in the bezel area BZ. For example, the movement of hydrogen contained in the lower buffer layer 110, the lower gate insulating layer 121, the lower interlayer insulating layer 131, the separation insulating layer 140, the upper buffer layer 150, the upper gate insulating layer 122, the first upper interlayer insulating layer 132 and the second upper interlayer insulating layer 160 toward the display area AA can be blocked by the barrier structure 700. The barrier structure 700 can surround the display area AA. Thus, in the display apparatus according to the embodiment of the present disclosure, the deviation in the characteristics of the driving circuits DC due to hydrogen moving from the bezel area BZ toward the display area AA can be prevented by the barrier structure 700. The barrier structure 700 can include a barrier line 710 and a cover pattern 720.

The barrier line 710 can be disposed close to the device substrate 100. For example, the barrier line 710 can be disposed between the device substrate 100 and the lower buffer layer 110 in the bezel area BZ. The barrier line 710 can be disposed on a same layer as the circuit light-blocking pattern 330. The barrier line 710 and the circuit light-blocking pattern 330 can be in direct contact with the upper surface of the device substrate 100. The barrier line 710 can include a same material as the circuit light-blocking pattern 330. The barrier line 710 can be formed by a same process as the circuit light-blocking pattern 330. For example, the barrier line 710 can be formed simultaneously with the circuit light-blocking pattern 330.

The barrier line 710 can include a hydrogen blocking material. For example, the barrier line 710 and the circuit light-blocking pattern 330 can include titanium (Ti). Thus, in the display apparatus according to the embodiment of the present disclosure, hydrogen moving toward the display area AA crossing the barrier line 710 can be absorbed on a surface of the barrier line 710. The barrier line 710 can extend along an edge of the display area AA. For example, a plane of the barrier line 710 can have a closed-loop shape surrounding the display area AA. Thus, in the display apparatus according to the embodiment of the present disclosure, hydrogen moving toward the display area AA in an outer area of the device substrate 100 can be blocked by the barrier line 710.

The plurality of inorganic insulating layer 110, 121, 122, 131, 132, 140, 150 and 160 disposed on the barrier line 710 can be separated by a barrier trench 700t. The barrier trench 700t can overlap the barrier line 710. For example, the barrier trench 700t can penetrate a portion of the lower buffer layer 110, a portion of the lower gate insulating layer 121, a portion of the lower interlayer insulating layer 131, a portion of the separation insulating layer 140, a portion of the upper buffer layer 150, a portion of the upper gate insulating layer 122, a portion of the first upper interlayer insulating layer 132 and a portion of the second upper interlayer insulating layer 160, which are disposed on an upper surface of the barrier line 710 opposite to the device substrate 100. Thus, in the display apparatus according to the embodiment of the present disclosure, the movement path of hydrogen through the lower buffer layer 110, the lower gate insulating layer 121, the lower interlayer insulating layer 131, the separation insulating layer 140, the upper buffer layer 150, the upper gate insulating layer 122, the first upper interlayer insulating layer 132 and the second upper interlayer insulating layer 160 can be cut by the barrier trench 700t. Therefore, in the display apparatus according to the embodiment of the present disclosure, the movement of hydrogen contained in the plurality of inorganic insulating layers 110, 121, 122, 131, 132, 140, 150 and 160 on the bezel area BZ can be blocked by the barrier trench 700t.

The cover pattern 720 can be disposed on a side-wall of the barrier trench 700t. For example, the side-wall of the barrier trench 700t can be covered by the cover pattern 720. The cover pattern 720 can be disposed on a same layer as the circuit drain electrode 295 and the circuit source electrode 297 of the circuit thin film transistor 290. For example, the cover pattern 720 can include an end portion disposed between the second upper interlayer insulating layer 160 and the lower planarization layer 171 of the bezel area BZ. The cover pattern 720 can include a same material as the circuit drain electrode 295 and the circuit source electrode 297. The cover pattern 720 can be formed by a same process as the circuit drain electrode 295 and the circuit source electrode 297. For example, the cover pattern 720 can be formed simultaneously with the circuit drain electrode 295 and the circuit source electrode 297. Thus, in the display apparatus according to the embodiment of the present disclosure, the side-wall of the barrier trench 700t can be completely covered by the cover pattern 720. And, in the display apparatus according to the embodiment of the present disclosure, the degradation of the process efficiency due to the formation of the barrier structure 700 can be prevented. Therefore, in the display apparatus according to the embodiment of the present disclosure, the deviation in the characteristics of the driving circuits DC due to the movement of hydrogen from the bezel area BZ to the display area AA can be prevented, without the degradation of the process efficiency.

The cover pattern 720 can include a hydrogen blocking material. For example, the cover pattern 720, the circuit drain electrode 295 and the circuit source electrode 297 can include titanium (Ti). The first drain electrode 215, the first source electrode 217, the second drain electrode 225 and the second source electrode 227 of each pixel area PA can include titanium (Ti). Thus, in the display apparatus according to the embodiment of the present disclosure, the movement of hydrogen through the plurality of inorganic insulating layers 110, 121, 122, 131, 132, 140, 150, and 160 of the bezel area BZ can be blocked by the cover pattern 720. The barrier trench 700t can exposed at least portion of the barrier line 710. The cover pattern 720 can be in direct contact with a portion of the barrier line 710 exposed by the barrier trench 700t. Therefore, in the display apparatus according to the embodiment of the present disclosure, the movement of hydrogen contained in the plurality of inorganic insulating layer 110, 121, 122, 131, 132, 140, 150, and 160 toward the display area AA from the bezel area BZ can be completely blocked by the barrier line 710 and the cover pattern 720. That is, in the display apparatus according to the embodiment of the present disclosure, hydrogen contained in the plurality of inorganic insulating layers 110, 121, 122, 131, 132, 140, 150, and 160 cannot penetrate into the display area AA by the barrier line 710 and the cover pattern 720.

The barrier trench 700t can include a region extending parallel to the barrier line 710. For example, the barrier trench 700t can be disposed parallel to sides of the display area AA that do not toward the gate driver GD and the pad area PAD. Thus, in the display apparatus according to the embodiment of the present disclosure, the movement of hydrogen contained in the plurality of inorganic insulating layer 110, 121, 122, 131, 132, 140, 150, and 160 toward the display area AA can be effectively blocked.

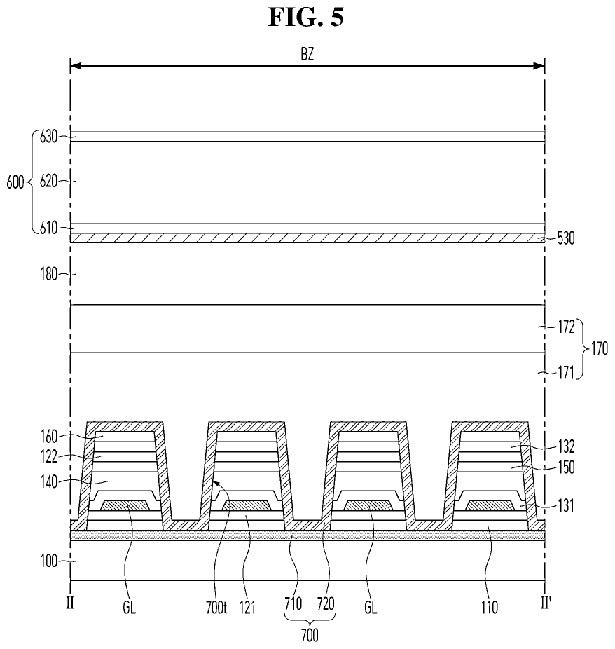

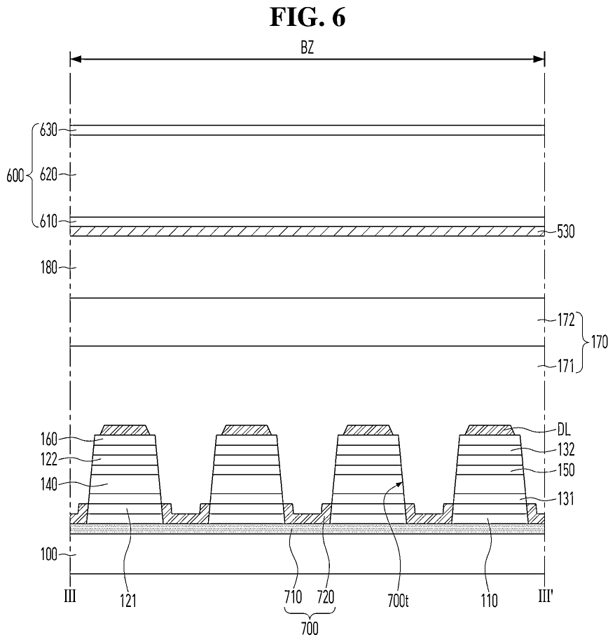

The barrier structure 700 can be disposed close to the display area AA. For example, the barrier structure 700 can cross between the display area AA and the gate driver GD and between the display area AA and the pad area PAD. The gate lines GL disposed between the gate driver GD and the display area AA and the signal wirings DL and PL disposed between the pad area PAD and the display area AA can cross the barrier structure 700. For example, the barrier line 710 can cross the gate lines GL and the data lines DL, as shown in FIGS. 1, 5 and 6.

The gate lines GL can be disposed on a different layer from the barrier line 710. For example, the gate lines GL can be disposed between the lower buffer layer 110 and the second upper interlayer insulating layer 160 of the bezel area BZ. The gate lines GL can be disposed on a same layer as the circuit gate electrode 293. For example, the gate lines GL can be disposed between the lower gate insulating layer 121 and the lower interlayer insulating layer 131. The gate lines GL can include a same material as the circuit gate electrode 293. The gate lines GL can be formed by a same process as the circuit gate electrode 293. For example, the gate lines GL can be formed simultaneously with the circuit gate electrode 293. The barrier trench 700t between the display area AA and the gate driver GD can be disposed between the gate lines GL. Thus, in the display apparatus according to the embodiment of the present disclosure, a portion of each gate line GL overlapping with the barrier line 710 can be surrounded by the barrier line 710 and the cover pattern 720. For example, in the display apparatus according to the embodiment of the present disclosure, hydrogen moving through the plurality of inorganic insulating layers 110, 121, 122, 131, 132, 140, 150, and 160 overlapping with the gate lines GL between the gate driver GD and the display area AA can be absorbed by the barrier line 710 and/or the cover pattern 720. Therefore, in the display apparatus according to the embodiment of the present disclosure, the movement of hydrogen contained in the plurality of inorganic insulating layer 110, 121, 122, 131, 132, 140, 150, and 160 between the gate driver GD and the display area AA can be prevented.

The data lines DL can be disposed on a same layer as the first drain electrode 215 of each pixel area PA. For example, the data lines DL can be disposed between the second upper interlayer insulating layer 160 and the lower planarization layer 171. The data lines DL can include a same material as the first drain electrode 215 of each pixel area PA. The data lines DL can be formed by a same process as the first drain electrode 215 of each pixel area PA. For example, the data lines DL can be formed simultaneously with the first drain electrode 215 of each pixel area PA. The data lines DL can include a same material as the cover pattern 720. For example, the data lines DL can include a hydrogen blocking material. Thus, in the display apparatus according to the embodiment of the present disclosure, the movement of hydrogen contained in the plurality of inorganic insulating layer 110, 121, 122, 131, 132, 140, 150, and 160 between the display area AA and the pad area PAD can be blocked by the barrier line 710, the cover pattern 720 and the data lines DL.

The barrier trench 700t between the display area AA and the pad area PAD can be disposed between the data lines DL. The cover pattern 720 can be spaced apart from the data lines DL. For example, the cover pattern 720 can expose an upper portion of the side-wall of the barrier trench 700t between the display area AA and the pad area PAD. A bottom surface and a lower portion of the side-wall of the barrier trench 700t can be covered by the cover pattern 720 between the display area AA and the pad area PAD. That is, in the display apparatus according to the embodiment of the present disclosure, the electrical connection between the data lines DL and the cover pattern 720 can be prevented. Therefore, in the display apparatus according to the embodiment of the present disclosure, the movement of hydrogen contained in the plurality of inorganic insulating layers 110, 121, 122, 131, 132, 140, 150, and 160 that are disposed between the display area AA and the pad area PAD can be blocked, without the distortion of a signal applied to the display area AA through the pad area PAD.

Accordingly, the display apparatus according to the embodiment of the present disclosure can include the plurality of inorganic insulating layers 110, 121, 122, 131, 132, 140, 150, and 160 disposed on the device substrate 100, the planarization layer 170 disposed on the plurality of inorganic insulating layers 110, 121, 122, 131, 132, 140, 150, and 160, the light-emitting devices 500 disposed on the planarization layer 170, the driving circuits DC disposed between the device substrate 100 and the planarization layer 170 in the display area AA, and the barrier structure 700 disposed between the device substrate 100 and the planarization layer 170 in the bezel area BZ, wherein the display area AA in which the light-emitting devices 500 are disposed can be surrounded by the barrier line 710 of the barrier structure 700, and wherein the side-wall of the barrier trench 700t penetrating the plurality of inorganic insulating layers 110, 121, 122, 131, 132, 140, 150 and 160 on the barrier line 710 can be covered by the cover pattern 720 of the barrier structure 700. Thus, in the display apparatus according to the embodiment of the present disclosure, the movement of hydrogen contained in the plurality of inorganic insulating layers 110, 121, 122, 131, 132, 140, 150 and 160 toward the display area AA from the bezel area BZ can be blocked by the barrier structure 700. That is, in the display apparatus according to the embodiment of the present disclosure, the deviation in the characteristics of the driving circuits DC due to hydrogen can be prevented. Therefore, in the display apparatus according to the embodiment of the present disclosure, the degradation in the quality of the image due to hydrogen can be prevented.

And, in the display apparatus according to the embodiment of the present disclosure, the barrier structure 700 can be formed using a process of forming the circuit light-blocking pattern 330 and a process of forming the data lines DL. Thus, in the display apparatus according to the embodiment of the present disclosure, the degradation of the process efficiency due to the formation of the barrier structure 700 can be prevented or at least reduced. Therefore, in the display apparatus according to the embodiment of the present disclosure, the production energy can be reduced by process optimization.

The display apparatus according to the embodiment of the present disclosure is described that the driving circuit DC of each pixel area PA can consist of the first thin film transistor TR1, the second thin film transistor TR2 and the storage capacitor Cst. However, in the display apparatus according to another embodiment of the present disclosure, the driving circuit DC of each pixel area PA can include a driving thin film transistor and at least one switching thin film transistor. For example, in the display apparatus according to another embodiment of the present disclosure, the driving circuit DC of each pixel area PA can further include a third thin film transistor for initializing the storage capacitor Cst according to the gate signal. The third thin film transistor of each pixel area PA can include a third semiconductor pattern, a third gate electrode, a third drain electrode and a third source electrode. The third semiconductor pattern of each pixel area PA can include a semiconductor material. The third gate electrode of each pixel area PA can be electrically connected to the corresponding gate line GL. The third drain electrode of each pixel area PA can be electrically connected to an initial line applying an initial signal. The third source electrode of each pixel area PA can be electrically connected to the storage capacitor Cst of the corresponding pixel area PA. Thus, in the display apparatus according to another embodiment of the present disclosure, the degree of freedom in configuration of the driving circuit DC in each pixel area PA can be improved.

In the display apparatus according to the embodiment of the present disclosure, the location and the electric connection of the first drain electrode 215, the first source electrode 217, the second drain electrodes 225 and the second source electrode 227 in each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode 215 of the corresponding driving circuit DC. Thus, in the display apparatus according to another embodiment of the present disclosure, the degree of freedom in the configuration of each driving circuit DC and the type of each thin film transistor TR1 and TR2 can be improved.

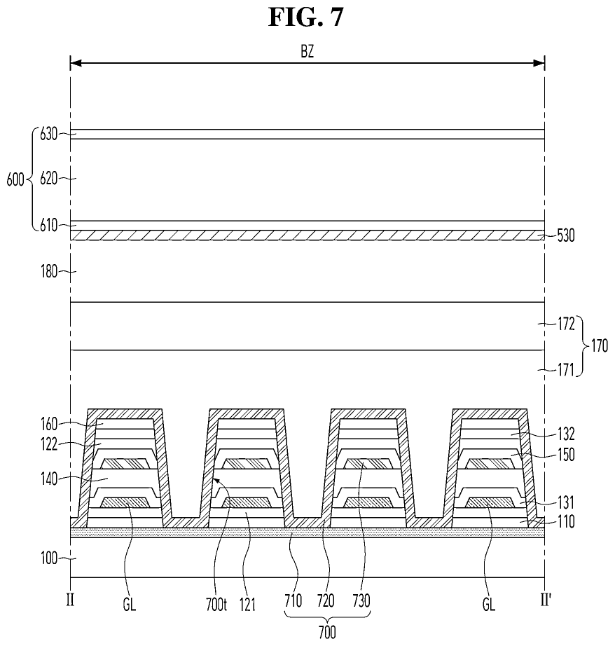

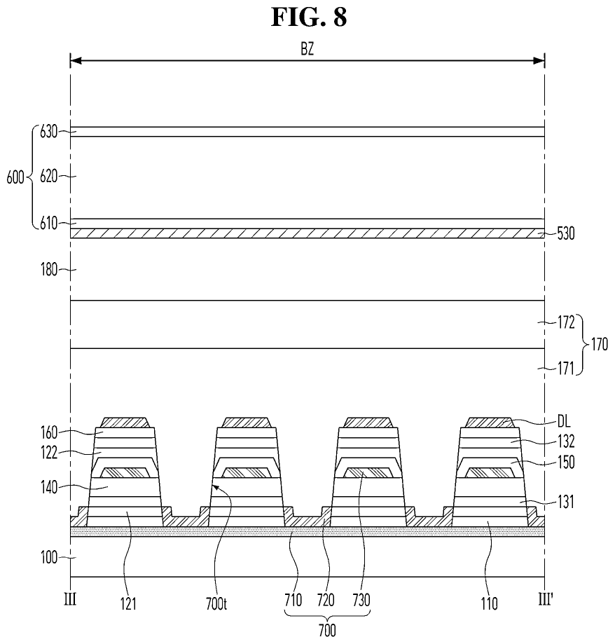

The display apparatus according to the embodiment of the present disclosure is described that the barrier structure 700 can consist of the barrier line 710 and the cover pattern 720. However, in the display apparatus according to another embodiment of the present disclosure, the barrier structure 700 can further include at least one barrier pattern disposed between the plurality of inorganic insulating layers 110, 121, 122, 131, 132, 140, 150, and 160 of the bezel area BZ. For example, in the display apparatus according to another embodiment of the present disclosure, the barrier structure 700 can include a barrier pattern 730 overlapping with the gate lines GL and the data lines DL, as shown in FIGS. 7 and 8. The barrier pattern 730 can include a hydrogen blocking material. Thus, in the display apparatus according to the embodiment of the present disclosure, the movement of hydrogen between the display area AA and the gate driver GD and between the display area AA and the pad area PAD can be blocked by the barrier pattern 730.

The barrier pattern 730 can be spaced apart from the gate lines GL and the data lines DL. The barrier pattern 730 can be disposed between the plurality of inorganic insulating layers 110, 121, 122, 131, 132, 140, 150 and 160 of the bezel area BZ. For example, the barrier pattern 730 can be disposed between the separation insulating layer 140 and the upper buffer layer 150. The barrier pattern 730 can be disposed on a same layer as the second light-blocking pattern of each pixel area PA. The barrier pattern 730 can include a same material as the second light-blocking pattern of each pixel area PA. The barrier pattern 730 can be formed by a same process as the second light-blocking pattern of each pixel area PA. For example, the barrier pattern 730 can be formed simultaneously with the second light-blocking pattern of each pixel area PA. Thus, in the display apparatus according to another embodiment of the present disclosure, the degradation of the process efficiency due to the formation of the barrier pattern 730 can be prevented or at least reduced. Therefore, in the display apparatus according to another embodiment of the present disclosure, the movement of hydrogen contained in the plurality of inorganic insulating layers 110, 121, 122, 131, 132, 140, 150, and 160 between the display area AA and the gate driver GD and between the display area AA and the pad area PAD can be effectively blocked.

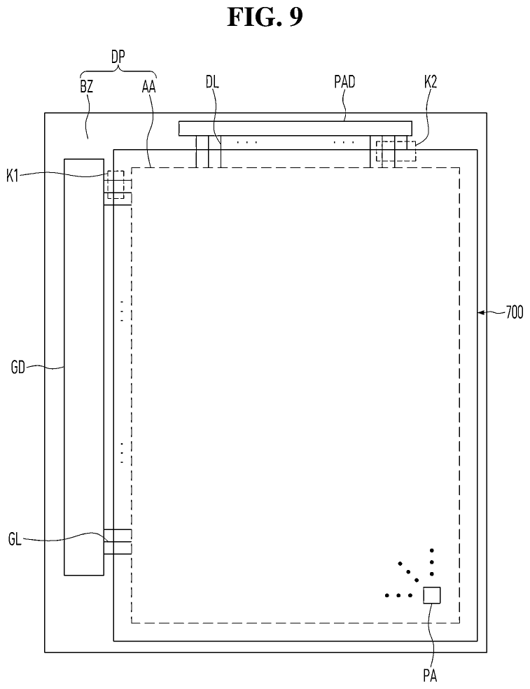

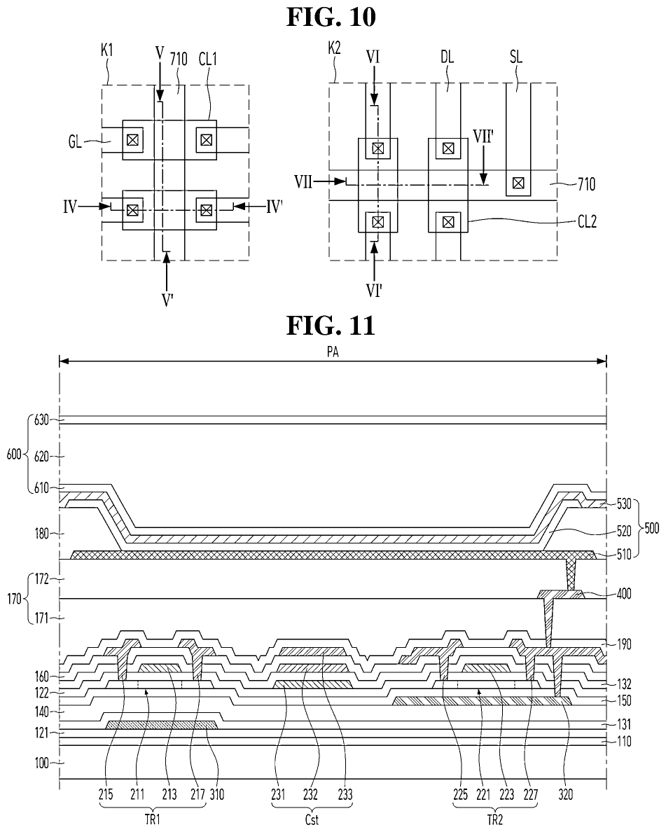

In the display apparatus according to another embodiment of the present disclosure, a specific signal can be applied to the barrier structure 700. For example, in the display apparatus according to another embodiment of the present disclosure, the barrier structure 700 can be electrically connected to the pad area PAD through a dummy signal wiring SL, as shown in FIGS. 9 and 10. The dummy signal wiring SL can be electrically connected to the barrier line 710 and/or the cover pattern 720. A signal applied to the barrier structure 700 through the dummy signal wiring SL can have a constant voltage. For example, a signal applied to the barrier structure 700 through the dummy signal wiring SL can be a low potential voltage (VSS). Thus, in the display apparatus according to another embodiment of the present disclosure, hydrogen diffusing toward the display area AA by the high-temperature process can be effectively blocked. And, in the display apparatus according to another embodiment of the present disclosure, noise signals travelling from outside toward the display area AA can be shielded by the barrier structure 700. Therefore, in the display apparatus according to another embodiment of the present disclosure, the malfunction of the pixel areas PA due to external noise can be prevented.

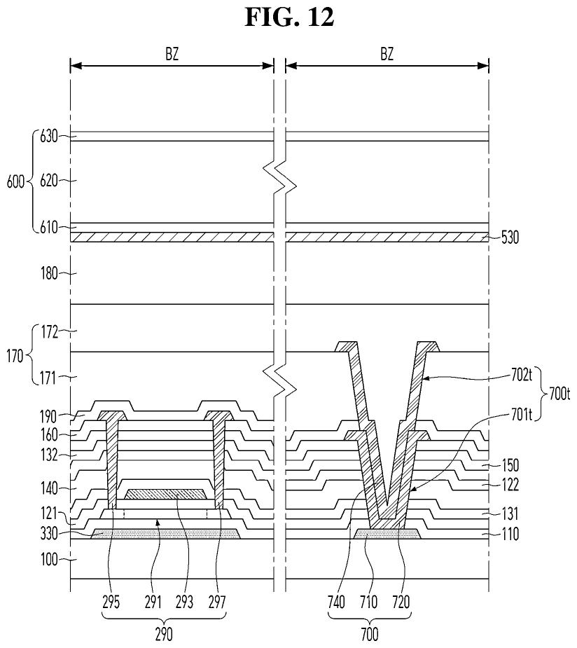

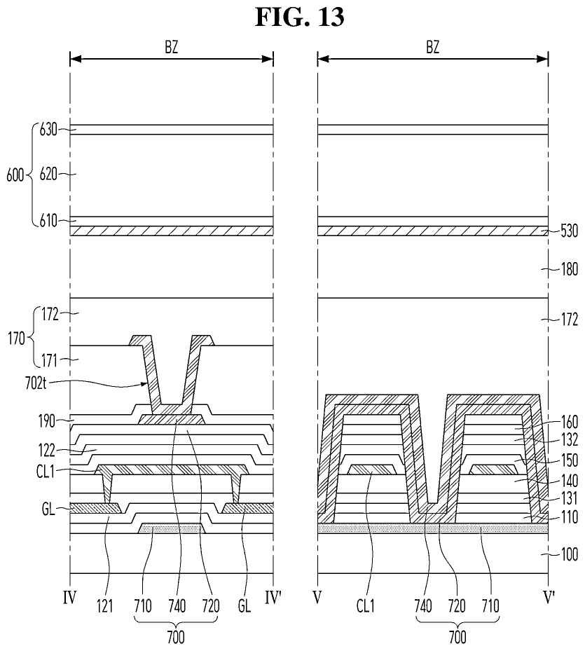

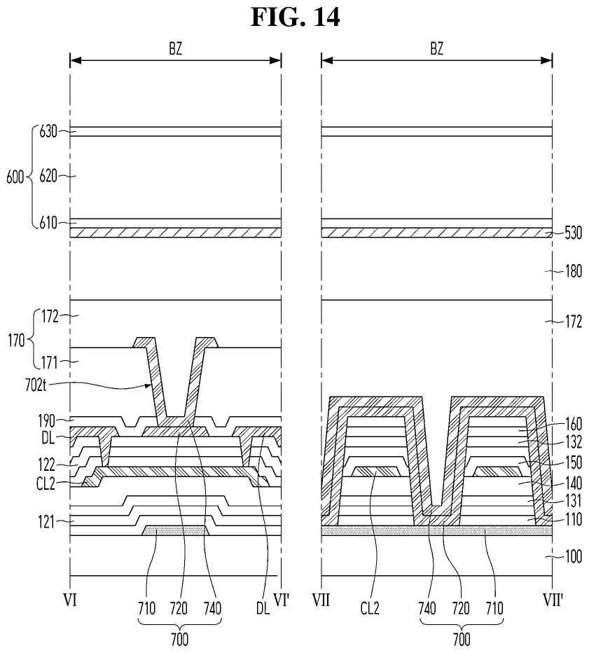

The display apparatus according to the embodiment of the present disclosure is described that the driving circuit DC of each pixel area PA can be covered by the lower planarization layer 171. However, in the display apparatus according to another embodiment of the present disclosure, at least one inorganic insulating layer can be disposed between the driving circuit DC of each pixel area PA and the lower planarization layer 171. For example, in the display apparatus according to another embodiment of the present disclosure, the first drain electrode 215, the first source electrode 217, the second drain electrode 225, and the second source electrode 227 of each pixel area PA can be covered by a device passivation layer 190, the lower planarization layer 171 can be disposed on the device passivation layer 190, and the device passivation layer 190 can be an inorganic insulating layer including an inorganic insulating material, such as silicon oxide (SiOx) and silicon nitride (SiNx), as shown in FIGS. 9 to 14.

The device passivation layer 190 can extend between the second upper interlayer insulating layer 160 and the lower planarization layer 171 of the bezel area BZ. For example, the circuit drain electrode 295 and the circuit source electrode 297 can be covered by the device passivation layer 190. The barrier trench 700t overlapping with the barrier line 710 can include a lower trench (sometimes also referred to as “lower barrier trench”) 701t penetrating the lower buffer layer 110, the lower gate insulating layer 121, the lower interlayer insulating layer 131, the separation insulating layer 140, the upper buffer layer 150, the upper gate insulating layer 122, the first upper interlayer insulating layer 132 and the second upper interlayer insulating layer 160 of the bezel area BZ, and an upper trench 702t penetrating the device passivation layer 190 and the lower planarization layer 171 of the bezel area BZ. The upper trench 702t can overlap the lower trench 701t. For example, the upper trench 702t can overlap a portion of the barrier line 710 exposed by the lower trench 701t. The barrier structure 700 can include a lower cover pattern 720 covering a side-wall of the lower trench 701t and an upper cover pattern 740 covering a side-wall of the upper trench 702t.

The lower cover pattern 720 can include a same material as the circuit drain electrode 295 and the circuit source electrode 297. The lower cover pattern 720 can include a hydrogen blocking material. The upper cover pattern 740 can be disposed on a same layer as the intermediate electrodes 400. For example, the upper cover pattern 740 can include an end portion disposed between the lower planarization layer 171 and the upper planarization layer 172. The upper cover pattern 740 can include a same material as the intermediate electrodes 400. The upper cover pattern 740 can be formed by a same process as the intermediate electrodes 400. For example, the upper cover pattern 740 can be formed simultaneously with the intermediate electrodes 400. The upper cover pattern 740 can include a hydrogen blocking material. For example, the upper cover pattern 740 and the intermediate electrodes 400 can include titanium (Ti). Thus, in the display apparatus according to another embodiment of the present disclosure, the movement of hydrogen from the bezel area BZ toward display area AA through at least one inorganic insulating layer 190 disposed on the driving circuit DC of each pixel area PA can be shielded by the upper trench 702t and the upper cover pattern 740. And, in the display apparatus according to another embodiment of the present disclosure, the degradation of the process efficiency due to the formation of the upper cover pattern 740 can be prevented. Therefore, in the display apparatus according to another embodiment of the present disclosure, the inflow of hydrogen through at least one inorganic insulating layer 190 disposed on the driving circuit DC of each pixel area PA can be blocked, without the degradation of the process efficiency.

In the display apparatus according to another embodiment of the present disclosure, the storage capacitor Cst of each pixel area PA can include a third capacitor electrode 233 disposed between the second upper interlayer insulating layer 160 and the device passivation layer 190. The third capacitor electrode 233 of each pixel area PA can include a same material as the first drain electrode 215, the first source electrode 217, the second drain electrode 225 and the second source electrode 227 of the corresponding pixel area PA. Thus, in the display apparatus according to another embodiment of the present disclosure, a size occupied by the storage capacitor Cst in each pixel area PA can be minimized.

In the display apparatus according to another embodiment of the present disclosure, each of the signal wirings GL and DL can be electrically connected to one of connection lines CL1 and CL2 crossing the barrier line 710. For example, each of the gate lines GL can cross the barrier line 710 by one of first connection lines CL1, and each of the data lines DL can cross the barrier line 710 by one of second connection lines CL2. Thus, in the display apparatus according to the embodiment of the present disclosure, the lower cover pattern 720 and the upper cover pattern 740 can surround the first connection lines CL1 between the gate driver GD and the display area AA, and the lower cover pattern 720 and the upper cover pattern 740 can surround the second connection lines CL2 between the pad area PAD and the display area AA. Therefore, in the display apparatus according to another embodiment of the present disclosure, the movement of hydrogen through the plurality of inorganic insulating layers 110, 121, 122, 131, 132, 140, 150, 160 and 190 disposed parallel to the gate lines GL and the data lines DL can be effectively blocked.

The connection lines CL1 and CL2 can be disposed between the lower buffer layer 110 and the second upper interlayer insulating layer 160 of the bezel area BZ. The connection lines CL1 and CL2 can include a hydrogen blocking material. For example, the connection lines CL1 and CL2 can be disposed on a same layer as the second light-blocking pattern 320 of each pixel area PA. The connection lines CL1 and CL2 can be disposed between the separation insulating layer 140 and the upper buffer layer 150 of the bezel area BZ. Thus, in the display apparatus according to another embodiment of the present disclosure, the inflow of hydrogen through the plurality of inorganic insulating layers 110, 121, 122, 131, 132, 140, 150, 160, and 190 disposed parallel to the gate lines GL and the data lines DL can be significantly reduced. Therefore, in the display apparatus according to another embodiment of the present disclosure, the reliability of the driving circuit DC in each pixel area PA can be greatly improved due to shielding the movement of hydrogen.

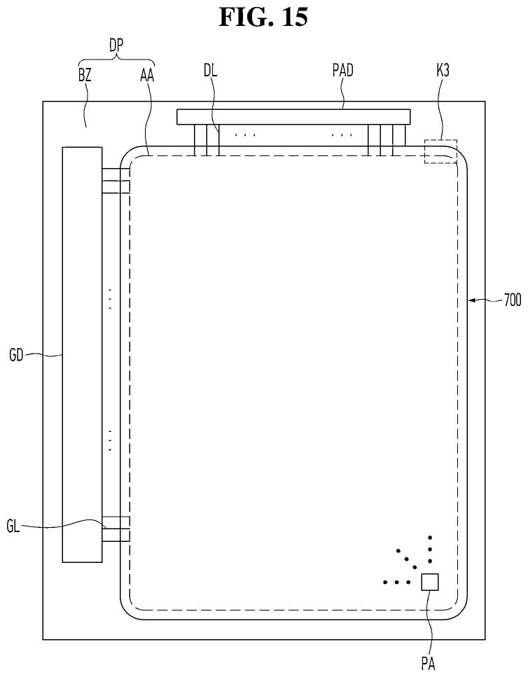

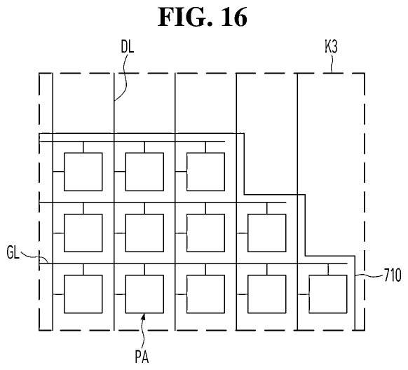

The display apparatus according to the embodiment of the present disclosure is described that each corner of the display area AA can have a right-angled shape. However, in the display apparatus according to another embodiment of the present disclosure, the display area AA can have various shapes. For example, in the display apparatus according to another embodiment of the present disclosure, each corner of the display area AA can be recognized as having a specific curvature, as shown in FIGS. 15 and 16 (wherein FIG. 16 is an enlarged view of the partial region K3 of FIG. 15). An end portion of the display area AA toward the pad area PAD or the gate driver GD can gradually decrease in width. For example, the number of the pixel areas PA can gradually decrease as it approaches the pad area PAD or the gate driver GD. Thus, in the display apparatus according to another embodiment of the present disclosure, the degree of freedom for the planar shape of the display area AA can be improved.

A plane of the barrier structure 700 can have a shape corresponding to the plane of the display area AA. For example, the barrier line 710 can extend along the pixel areas PA disposed on the outermost side of the display area AA. A distance between the pixel areas PA disposed on the outermost side of the display area AA and the barrier line 710 can be constant. Thus, in the display apparatus according to another embodiment of the present disclosure, the deviation in the amount of hydrogen penetrating toward the display area AA from the bezel area BZ can be minimized. Therefore, in the display apparatus according to another embodiment of the present disclosure, the deviation in the characteristics of the driving circuits due to hydrogen can be effectively reduced.

In the result, the display apparatus according to the embodiments of the present disclosure can comprise the plurality of inorganic insulating layers disposed on the device substrate, the light-emitting devices disposed on the plurality of inorganic insulating layers, the barrier line disposed between the device substrate and the plurality of inorganic insulating layers, and the cover pattern covering the side-wall of the barrier trench penetrating the plurality of inorganic insulating layers, wherein the display area in which the light-emitting devices are disposed can be surrounded by the barrier line, wherein the barrier line can include a hydrogen blocking material, and wherein the barrier trench can overlap the barrier line. Thus, in the display apparatus according to the embodiments of the present disclosure, hydrogen moving toward the display area from the outside of the device substrate can be blocked by the barrier line and the cover pattern. Thereby, in the display apparatus according to the embodiments of the present disclosure, the deviation in the characteristics of the driving circuits electrically connected to the light-emitting device due to hydrogen can be minimized. And, in the display apparatus according to the embodiments of the present disclosure, the production energy can be reduced by process optimization.

What is claimed is:

1. A display apparatus comprising:
a device substrate including a bezel area surrounding a display area;
a plurality of inorganic insulating layers on the device substrate, the plurality of inorganic insulating layers including an inorganic insulating material;
a planarization layer on the plurality of inorganic insulating layers, the planarization layer including an organic insulating material;
a barrier line between the device substrate and the plurality of inorganic insulating layers in the bezel area, the barrier line including a hydrogen blocking material;
a barrier trench penetrating the plurality of inorganic insulating layers in the bezel area, the barrier trench overlapping with the barrier line;
a cover pattern between the plurality of inorganic insulating layers and the planarization layer, the cover pattern covering a side-wall of the barrier trench; and
a light-emitting device on the planarization layer, the light-emitting device overlapping with the display area,
wherein the barrier line extends along an edge of the display area.

2. The display apparatus according to claim 1, wherein the barrier trench includes a region extending parallel to the barrier line.

3. The display apparatus according to claim 1, wherein the cover pattern includes a hydrogen blocking material.

4. The display apparatus according to claim 1, wherein the barrier trench exposes at least portion of the barrier line and the cover pattern is in contact with a portion of the barrier line that is exposed by the barrier trench.

5. The display apparatus according to claim 1, further comprising:
signal wirings crossing the barrier line on a side of the display area,
wherein the signal wirings are on a different layer from the barrier line and the barrier trench is between the signal wirings.

6. The display apparatus according to claim 5, wherein the signal wirings are between the plurality of inorganic insulating layers and the planarization layer and the cover pattern exposes an upper portion of the side-wall of the barrier trench.

7. The display apparatus according to claim 1, further comprising:
a circuit thin film transistor on the bezel area; and
a circuit light-blocking pattern between the device substrate and the circuit thin film transistor in the bezel area,
wherein the plurality of inorganic insulating layers include a lower gate insulating layer covering a semiconductor pattern of the circuit thin film transistor and a lower interlayer insulating layer covering a gate electrode of the circuit thin film transistor, and
wherein the circuit light-blocking pattern is on a same layer as the barrier line.

8. The display apparatus according to claim 7, wherein the barrier line includes a same material as the circuit light-blocking pattern.

9. The display apparatus according to claim 7, wherein a drain electrode and a source electrode of the circuit thin film transistor is on a same layer as the cover pattern.

10. The display apparatus according to claim 9, wherein the cover pattern includes a same material as the drain electrode and the source electrode of the circuit thin film transistor.

11. The display apparatus according to claim 1, wherein a distance between pixel areas disposed on an outermost side of the display area and the barrier line is constant.

12. A display apparatus comprising:
a driving circuit on a display area of a device substrate;
a planarization layer on the driving circuit, the planarization layer extending onto a bezel area of the device substrate;
a plurality of inorganic insulating layers between the device substrate and the planarization layer, the plurality of inorganic insulating layers overlapping with the display area and the bezel area;
a barrier structure on the bezel area of the device substrate, the barrier structure surrounding the display area; and
a light-emitting device on the planarization layer of the display area, the light-emitting device electrically connected to the driving circuit,
wherein the barrier structure includes a barrier line including a hydrogen blocking material and a lower cover pattern on a side-wall of a lower barrier trench that penetrates the plurality of inorganic insulating layers, and
wherein the barrier line is between the device substrate and the lower barrier trench in the bezel area.

13. The display apparatus according to claim 12, wherein the barrier line is in contact with the device substrate in the bezel area.

14. The display apparatus according to claim 12, wherein the lower cover pattern includes a hydrogen blocking material.

15. The display apparatus according to claim 12, further comprising:
a device passivation layer between the driving circuit and the planarization layer, the device passivation layer including an inorganic insulating material,
wherein the device passivation layer extends between the plurality of inorganic insulating layers and the planarization layer in the bezel area, and
wherein the barrier structure includes an upper cover pattern on a side-wall of an upper trench that penetrates the device passivation layer.

16. The display apparatus according to claim 15, wherein the upper cover pattern includes a hydrogen blocking material.

17. The display apparatus according to claim 15, further comprising:
an intermediate electrode connecting the light-emitting device to the driving circuit,
wherein the planarization layer includes a lower planarization layer and an upper planarization layer on the lower planarization layer,
wherein the intermediate electrode is between the lower planarization layer and the upper planarization layer in the display area, and
wherein the upper cover pattern includes a same material as the intermediate electrode.

18. The display apparatus according to claim 17, wherein the upper trench penetrates the lower planarization layer in the bezel area and the upper cover pattern is on a same layer as the intermediate electrode.

19. The display apparatus according to claim 12, wherein a distance between pixel areas disposed on an outermost side of the display area and the barrier line is constant.
